(19) United States
(12) Patent Application Publication
(10) Pub. No.: US 2003/0010936 A1
(43) Pub. Date: Jan. 16, 2003

(54) Optically detectable alignment marks producing an enhanced signal-amplitude change from scanning of a detection light over the alignment mark, and associated alighment-detection methods

(75) Inventors: Jin Udagawa, Fukaya-shi (JP); Noriyuki Hirayanagi, Tokyo (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation

(21) Appl. No.: 10/188,580

(22) Filed: Jul. 3, 2002

(30) Foreign Application Priority Data
Jul. 10, 2001 (JP) 2001-208656

(51) Int. Cl. G21K 5/10; H01J 37/08

(52) U.S. Cl. 250/492.21

(57) ABSTRACT

Alignment marks are disclosed that provide, when scanned by a detection-light beam, an enhanced signal-amplitude change. Such an alignment mark is formed on a mark substrate and is used for performing an alignment in a charged-particle-beam (CPB) microlithography system. The alignment mark includes at least one mark element defined as a corresponding height-difference characteristic in the mark substrate. The mark element includes more than two height-difference edges that would be encountered by a detection-light beam being scanned across the element. The height-difference edges of the element can be defined by multiple individual mark-element components that collectively provide the more than two height-difference edges of the mark element. Alternatively, for example, the element can include two height-difference edges at respective edges of the mark element and at least one height-difference edge situated between the two height-difference edges at respective edges of the mark element. The alignment mark is suitable for detection by an optical alignment-detection device of a CPB microlithography system.

### FIELD

This disclosure pertains to microlithography (transfer of a pattern, as defined on a reticle or mask (termed “reticle” herein) to a substrate using an energy beam). Microlithography is a key technology used in the manufacture of microelectronic devices such as integrated circuits (e.g., microprocessor and memory chips), displays (e.g., liquid-crystal and other types of panel displays), magnetic pickup heads, image sensors (e.g., CCDs), and micromachines. More specifically, in the context of microlithography performed using a charged particle beam such as an electron beam or ion beam, the disclosure pertains to optically detectable alignment marks and to methods for using such marks for aligning the reticle.

### BACKGROUND

In recent years, as the line-width of critical circuit elements in microelectronic devices has continued to decrease, the resolution limitations of optical microlithography (i.e., microlithography performed using a beam of deep or vacuum UV light) have become apparent. Consequently, much effort currently is being expended in the development of “next generation” microlithography technology. A promising candidate technology in this regard is charged-particle-beam (CPB) microlithography.

Unfortunately, the currently most practical CPB microlithography approaches in terms of minimizing aberrations and utilizing a manufacturable reticle cannot expose an entire pattern in one exposure “shot.” Consequently, throughput remains a key concern in the development of a practical CPB microlithography system. For some applications, satisfactory throughput has been obtained with the so-called “divided-reticle reduction” CPB microlithography, in which the pattern to be transferred in defined on a reticle segmented (divided) into a large number of exposure units (usually termed “subfields”). Each of the subfields defines a respective portion of the overall pattern, formed on the reticle in advance of exposure. The subfields are exposed in sequence, and the corresponding images of the subfields are formed on the substrate in a manner such that the images are “stitched together” in a contiguous manner to form the entire pattern. The term “reduction” denotes the fact that the image formed on the substrate is smaller (by an integer ratio) than the corresponding image as defined on the reticle. The integer ratio is the “demagnification ratio” of the projection-optical system that transfers the image from the reticle to the substrate. Typical demagnification ratios are ¼ or ⅕. So as to be imprintable with the image, the surface of the substrate (typically a semiconductor wafer) is coated with a suitable “resist.” Typically, each subfield on the reticle is dimensioned about 1 mm square. Hence, at a ¼ demagnification ratio, the corresponding image as formed on the substrate is dimensioned 0.25 mm square. Even though these subfields are exposed sequentially one at a time, the throughput realized with this approach is substantially improved over the older techniques (still used for reticle-making) of directly “drawing” the pattern line-by-line and of the so-called “cell” or “character” projection methods.

Whenever CPB microlithography of a substrate is performed using a reticle, it is necessary to determine certain positional relationships very accurately. One such positional relationship is that of the irradiation position of the charged particle beam on the reticle. Another such positional relationship is that of the reticle and substrate relative to each other. These measurements are performed with the aid of “alignment marks” provided on or at the reticle and substrate. For example, the alignment marks can be defined directly on the reticle and substrate, and/or on the respective stages that hold the reticle and substrate -for exposure.

In existing microlithography systems, detection of alignment marks usually is performed using an optical microscope equipped with a two-dimensional image sensor such as a charge-coupled device (CCD) or the like. For detection, an alignment mark is illuminated with a “detection-light beam.” Light from the illuminated mark propagates to the optical microscope, which is used to detect the position of the mark. The image of the mark formed on the CCD is processed to determine whether the desired exact alignment has been obtained. Detection of positional alignments in this manner is effective because of the flexibility inherent in processing of an optical image. Light having a broad spectral bandwidth is desirable for use as the illumination light for the alignment mark(s) because such light tends to be relatively unaffected by variations in the condition of the surface of the alignment mark. Thus, highly accurate position detections can be performed.

An exemplary conventional alignment mark as used for optical alignment detection is depicted in FIGS. 7(a)-7(c). FIG. 7(a) is a plan view of the alignment mark 71; FIG. 7(b) is an enlargement of an element of the alignment mark; and FIG. 7(c) is an elevational section along the line E-E′ of FIG. 7(b), showing the characteristic “height difference” manifest in each element of the mark. As shown in FIG. 7(a), a conventional alignment mark 71 defines a “height-difference” pattern comprising multiple elements extending across each other. The height-difference pattern is formed by etching a mark substrate (which can be the reticle or a plate on the reticle stage, for example) with an alignment-mark pattern. Differential etching yields the depicted height difference in each element of the mark (FIG. 7(c)). I.e., the elements 73 are “lower” than surrounding material, with abrupt edges 75. Whenever a beam of detection light is irradiated onto the alignment mark 71, the detection light is scattered by the edges 75 of each element. This scattering causes a corresponding change in signal amplitude detected by the CCD of the optical microscope. By detecting the change in signal amplitude strength as the mark-detection beam is scanned over the mark 71, the position of the alignment mark is detected.

In view of the conventional manner of detecting the position of an alignment mark based on signal amplitude, as summarized above, it is especially desirable that the change in signal amplitude produced by the beam passing over the elements 73 be as large as possible. However, measurable changes in signal amplitude are produced only as the beam passes over the edges 75 of the alignment-mark elements 73, and the magnitude of change in signal amplitude at such locations is typically rather low. Hence, this conventional method of detecting the positions of alignment marks is limited in its capacity to exhibit any improvement in mark-detection accuracy.

### SUMMARY

In view of the shortcomings of conventional alignment-mark-detection methods as summarized above, the present invention provides, inter alia, alignment marks that produce substantially greater changes in signal amplitude obtained using an optical alignment-detection device than conventional alignment marks. Also provided are mark-detection methods performed using the improved alignment marks.

According to a first aspect of the invention, alignment marks are provided that are formed on a mark substrate and used for performing an alignment in a charged-particle-beam (CPB) microlithography system. An embodiment of such an alignment mark comprises at least one mark element defined as a corresponding height-difference characteristic in the mark substrate. For alignment purposes the alignment mark is scanned by a light beam from a detection-light source. Detection light reflected and scattered by the alignment mark is directed by an optical microscope to a detector (e.g., CCD or the analogous detector) that produces an electrical signal corresponding to the light received by the detector. The mark element comprises more than two height-difference edges that are encountered by the beam of detection light being scanned across the element. As a result of the increased number of height-difference edges, the corresponding electrical signal experiences greater changes in amplitude as the beam passes over the element. I.e., the increased number of height-difference edges imparts more scattering to the beam of detection light, yielding a greater change in signal amplitude than obtained by scanning a conventional alignment mark having only two height-difference edges per element.

The alignment mark desirably comprises multiple mark elements arranged at right angles to each other. In this configuration each mark element can comprise the more than two height-difference edges that would be encountered by a detection-light beam being scanned across the element.

The mark substrate on which the alignment mark is formed can be a CPB microlithography reticle, or can be separate from the reticle. As an example of the latter, the alignment mark can be on a mark plate located on the reticle stage.

According to a more specific configuration, the at least one element of the alignment mark can comprise multiple individual mark-element components that collectively provide the more than two height-difference edges of the mark element. For example, each component can be a line-shaped component of the mark element, in which configuration the components can be arranged parallel to each other in the element. Also, the line-shaped components can be arranged in the element with a respective prescribed space interval between adjacent line-shaped components. The “prescribed space intervals” can be equal to each other or can be different.

Desirably, each prescribed interval between adjacent mark-element components is no greater than a resolution limit of the optical system of the alignment-detection device used for detecting the alignment mark. With an alignment mark configured in this manner, the corresponding signal produced when the detection-light beam passes over the element exhibits a simple profile (a single leading edge and a single trailing edge, which reduces detection noise and increases the amplitude of the signal. In any event, by dividing one or more mark elements into multiple mark-element components, the resulting signal exhibits an amplitude-change profile that yields higher alignment-detection accuracy.

According to another more specific configuration, the mark element comprises two height-difference edges at respective edges of the mark element and at least one height-difference edge situated between the two height-difference edges at respective edges of the mark element. As with the first more specific configuration summarized above, this second more specific configuration provides the mark element with more height differences than a corresponding element on a conventional alignment mark, which produces a higher-amplitude signal change whenever a detection-light beam, scanned over the element, is detected. The spacing between the height-difference edges in the element can be the same or different. Desirably, the at least one height-difference edge situated between the two height-difference edges at respective edges of the mark element is separated from the two height-difference edges at the respective edges of the mark element by a prescribed interval that is no greater than a resolution limit of an optical system of an alignment-detection device used for detecting the alignment mark.

According to another aspect of the invention, reticle-alignment-detection methods are provided in the context of a CPB microlithography method. In an embodiment of such a method, an alignment mark is defined on the reticle. The mark can be configured according to, for example, any of the mark configurations summarized above. A detection-light beam is directed to the alignment mark and scanned across the element. Light of the detection-light beam reflected from the alignment mark is detected as the detection-light beam is scanned across the element. From the detected light, a corresponding electrical signal is produced that exhibits amplitude changes corresponding to passage of the detection-light beam over the height-difference edges of the element. The electrical signal is processed to determine an alignment position of the reticle.

The foregoing and additional features and advantages of the invention will be more readily apparent from the following detailed description, which proceeds with reference to the accompanying drawings.

### BRIEF DESCRIPTION OF THE DRAWINGS

FIGS. 1(a)-1(c) depict a first representative embodiment of an alignment mark, wherein FIG. 1(a) is a plan view of the alignment mark, FIG. 1(b) is an enlargement of a portion of an element of the mark showing multiple line-shaped components of the element, and FIG. 1(c) is an elevational section along the line A-A′ of FIG. 1(b).

FIG. 2(a) depicts an image of the alignment mark of FIG. 1(a) as detected by an optical alignment-detection device, and FIG. 2(b) is a plot of an exemplary signal produced by a scan of a detection-light beam along the Y-direction line B-B′ in FIG. 2(a).

FIGS. 3(a)-3(c) depict a second representative embodiment of an alignment mark, wherein FIG. 3(a) is a plan view of the alignment mark, FIG. 3(b) is an enlargement of a portion of an element of the mark, and FIG. 3(c) is an elevational section along the line C-C′ of FIG. 3(b).

FIG. 4 is a schematic elevational diagram of an embodiment of an electron-beam microlithography system capable of detecting an alignment mark according to any of various embodiments thereof.

FIG. 5 is a schematic diagram of an optical alignment-detection device of the system of FIG. 4.

FIG. 6(a) is an image, for comparison purposes, of a conventional alignment mark as detected by the device of FIG. 4, and FIG. 6(b) is a plot of the electrical signal, produced by the device of FIG. 4, accompanying a sweep of a detection-light beam along the Y-direction line D-D′ in FIG. 6(a).

FIGS. 7(a)-7(c) depict a conventional alignment mark, wherein FIG. 7(a) is a plan view of the alignment mark, FIG. 7(b) is an enlargement of a portion of an element of the mark, and FIG. 7(c) is an elevational section along the line E-E′ of FIG. 7(b).

### DETAILED DESCRIPTION

The invention is described below in the context of representative embodiments that are not intended to be limiting in any way. Also, the embodiments are described in the context of performing charged-particle-beam (CPB) microlithography using an electron beam as an exemplary charged particle beam. It will be understood that the principles of CPB microlithography described below are applicable with equal facility to use of an alternative charged particle beam such as an ion beam.

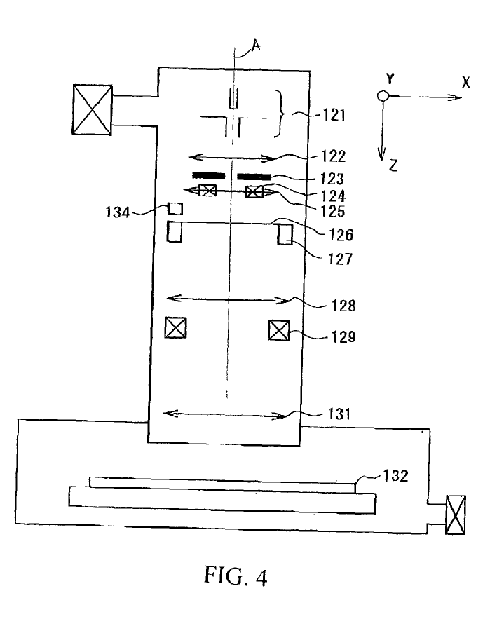

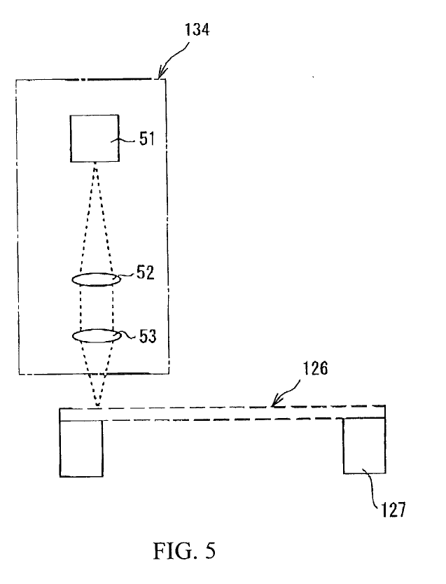

Reference is made first to FIGS. 4 and 5 that depict relevant aspects of electron-beam microlithography and of alignment-mark detection. FIG. 4 is a schematic drawing of an embodiment of an electron-beam microlithography system. An electron gun 121 (serving as the source of the charged particle beam) is situated at the extreme upstream end of the depicted electron-optical system. The electron gun 121 emits an electron “illumination beam” in the downstream direction (downward in the figure).

The illumination beam from the electron gun 121 passes through a condenser lens system 122 and through a beam-shaping aperture 123 situated downstream of the condenser lens system 122. An image of the beam-shaping aperture 123 is formed on the reticle 126 by an illumination lens 125. The beam-shaping aperture 123 trims the illumination beam (as the beam passes through the aperture) such that the illumination beam with a transverse profile sufficient for illumination of only one exposure unit (subfield) on the reticle at a given instant in time. The electron-optical components, described above and below, situated between the electron gun 121 and the reticle 126 collectively constitute the “illumination-optical system.”

A blanking deflector and blanking aperture (neither is shown in the figure, but both are well understood in the art) and an illumination-beam deflector 124 are situated downstream of the beam-shaping aperture 123. During times in which illumination of the reticle 126 with the illumination beam is not necessary, the blanking deflector deflects the illumination beam laterally to cause the beam to be blocked by a plate defining the blanking aperture. Thus, a “blanked” illumination beam is prevented from propagating downstream to the reticle 126. The illumination-beam deflector 124 deflects the illumination beam laterally as required to illuminate the subfields of the reticle. The subfields that are illuminated are those located within the optical field of the illumination-optical system, in which the subfields are illuminated in a sequential manner by appropriate deflections of the illumination beam (in the X-direction in FIG. 4).

Situated downstream of the beam-shaping aperture 123 is the illumination lens 125, which collimates the illumination beam and directs the collimated beam to the reticle 126. Thus, as noted above, an image of the beam-shaping aperture 123 is formed on the reticle 126.

The reticle 126 is, for example, a scattering-membrane or scattering-stencil reticle that extends in a plane (X-Y plane) that is perpendicular to the optical axis A of the depicted electron-optical system. As noted above, the reticle 126 defines the prescribed pattern (chip pattern) used for forming a layer in the microelectronic device(s) formed on a downstream substrate 132.

Peripheral portions of the reticle 126 are supported on a reticle stage 127 that is movable in the X-direction and Y-direction. Thus, the reticle 126 is moved mechanically as required to position individual rows of subfields in the optical field of the illumination-optical system. As each such row is positioned within the optical field, the illumination beam is deflected as required by the illumination-beam deflector 124 to illuminate the respective subfields in the row.

Between the reticle 126 and the substrate 132 is a “projection-optical system” that comprises projection lenses 128, 131 and a deflector 129. As the illumination beam illuminates a selected subfield on the reticle, portions of the beam passing through the illuminated subfield constitute a “patterned beam” that carries an aerial image of the pattern portion defined in the illuminated subfield. The patterned beam is “reduced” (demagnified) by passage through the projection lenses 128, 131 and directed to a respective location on the upstream-facing surface of the substrate 132. For forming the image at the desired location on the substrate, the patterned beam is deflected in a lateral direction by the deflector 129. So as to be imprintable with the projected image, the upstream-facing surface of the substrate is coated with a suitable “resist.” As the resist receives an exposure “dose” by the patterned beam, the respective aerial image is imprinted into the resist. Thus, the pattern is “transferred” from the reticle 126 to the substrate 132.

Referring now to FIG. 5, the apparatus of FIG. 4 further comprises an alignment-detection device 134 that optically detects the position of an alignment mark on the reticle 126. Also shown in FIG. 5 is the reticle stage 127 with the reticle 126 mounted thereon. The reticle stage 127 is “driven,” based at least in part upon reticle-position data obtained by the alignment-detection device 134, to position the reticle for exposure of the subfields from the reticle 126 to the substrate 132. The alignment-detection device 134 in this embodiment is configured as an optical microscope that receives a detection-light beam reflected from an alignment mark on the reticle 126 or reticle stage 127. The detection-light beam is produced by a light source (not shown but well understood in the art). The detection-light beam is of a wavelength to which the resist on the substrate 132 is not sensitive. The detection-light beam is directed by illumination optics (not shown but well understood in the art) to the alignment mark. Light of the beam reflected by the mark propagates to the alignment-detection device 134, comprising a detection-optical system 52, 53 that enlarges and projects an image of the alignment mark onto a detector 51 (e.g., CCD). As the alignment mark is illuminated by the beam of detection light, the light is scattered by edges of the mark elements (height-difference pattern elements). The changes in signal amplitude produced by the detection-light beam as the beam passes over the edges are detected by the detector 51. Image processing of this amplitude-change data is performed to determine the position of the alignment mark.

A representative embodiment of an alignment mark incorporates the height-difference principle described above. The alignment mark can be defined directly on the reticle 126 (which can be made from, for example, a silicon wafer or a diamond-like carbon substrate). As noted above, changes in signal amplitude that are detected by the alignment-detection device 134 are caused by passage of the detection-light beam over edges of the height-difference pattern elements of the alignment mark.

According to the invention, the change in signal amplitude accompanying passage of the detection-light beam over the alignment-mark elements is increased substantially by providing an increased number (i.e., greater than two) of height-difference edges associated with each element of the alignment mark than conventionally. For example, in a first representative embodiment of an alignment mark, each single height-difference element present on a conventional alignment mark is divided into multiple height-difference components (e.g., line-shaped components or square-dot components). Consequently, each element of the alignment mark has many (more than the conventional two) edges. By increasing the number of edges per element, the change in signal amplitude produced by a beam of detection light passing over each element is increased substantially over the change produced by a conventional alignment mark. Thus, use of an alignment mark according to this embodiment allows alignment-mark detections to be performed with substantially greater accuracy than conventionally.

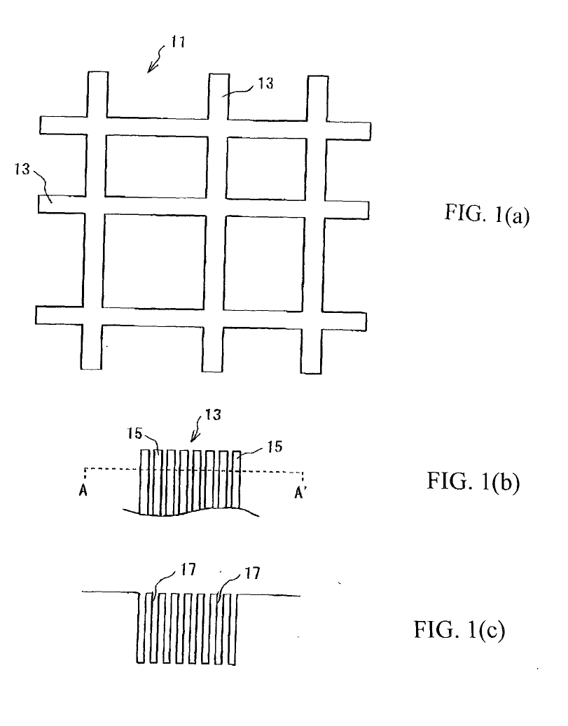

More specifically, turning to FIGS. 1(a)-1(C), the first representative embodiment of an alignment mark is depicted. FIG. 1(a) is a plan view of the alignment mark 11, FIG. 1 (b) is an enlargement of a portion of an element 13 of the mark showing the line-shaped components 15 of each element 13, and FIG. 1(c) is an elevational section along the line A-A′, showing the height-difference profile produced by the line-shaped components 15. In FIG. 1(a), the alignment mark 11 comprises multiple elements 13 arranged at right angles to each other and crossing each other. As shown in FIG. 1 (b), each element comprises multiple line-shaped components 15 arrayed at a prescribed interval (e.g., 1.2 μm spacing between adjacent components 15). The height-difference profile defined by the line-shaped components 15 are shown in FIG. 1(c). Thus, each element 13 is provided with many (more than two) height-difference edges 17 across the width of the element 13. As the detection-light beam passes over the element 13, the beam encounters the many height-difference edges, each of which causing scattering of the light. The corresponding change in signal amplitude as the detection-light beam passes over each element 13 is increased substantially compared to the changes in amplitude produced by conventional alignment marks.

In this embodiment, the width and inter-line spacing of the line-shaped components 15 is 1.2 μm, but these dimensions are not intended to be limiting in any way. Also, the width of each component 15 need not be the same, and it is not necessary that the inter-line spacing be the same between each pair of components 15. The elements 13 can be configured in any of various ways to provide an increased number of height-difference edges.

For the greatest changes in signal amplitude, the individual inter-line spacings of the line-shaped components 15 in this embodiment desirably do not exceed the resolution limit of the optical system of the alignment-detection device 134. In general, the resolution of the alignment-detection device 134 is a function of the wavelength μ of the source of the detection-light beam and of the numerical aperture (NA) of the detection-optical system 52, 53, and is expressed by the following equation:

Resolution=λ/NA

For example, if the wavelength of the detection-light source is 550 nm (which is about the median wavelength of white light), and if the NA of the optical system of the alignment-detection device 134 is 0.3, then the resolution is approximately 1.83 μm. In such a situation, if the line-shaped components 15 are spaced apart in the elements 13 by less than 1.83 μm, then the components will not be resolved, and the multiple components 15 per element 13 will be detected as a single height-difference signal. Since the multiple components 15 do not produce significant detection noise, the change in the signal amplitude is substantially greater than obtained from a conventional alignment mark, which substantially improves mark-detection accuracy.

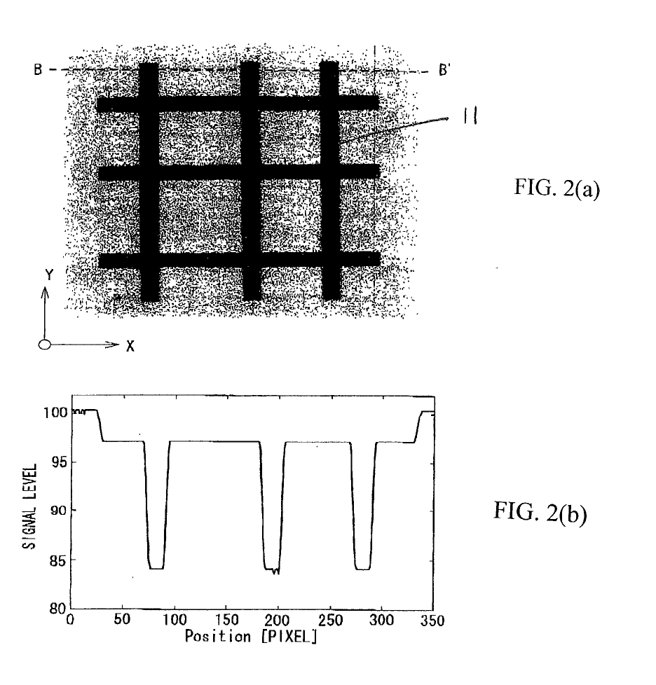

FIG. 2(a) depicts an image of an alignment mark 11, according to the first representative embodiment, as detected by the optical alignment-detection device 134. The alignment mark 11 is defined on a reticle formed from a silicon substrate. FIG. 2(b) is a plot of an exemplary signal produced by a scan of the detection-light beam along the Y-direction line B-B′ in FIG. 2(a). As shown in FIG. 2(a), the multiple line-shaped components in each element are not resolved in the image. Rather, each element of the mark is detected as a single respective signal-amplitude profile. The great height of the signal profile produced by each element indicates that the elements of the mark are detected with high contrast. FIG. 2(b) also shows that the individual components of each element were not resolved in the signal. Thus, for each element of the mark, a single height-difference profile having high contrast is produced.

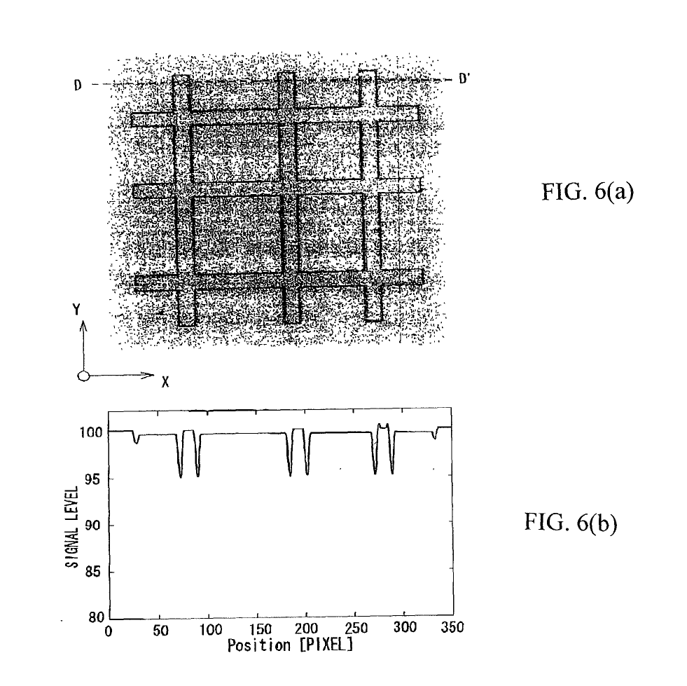

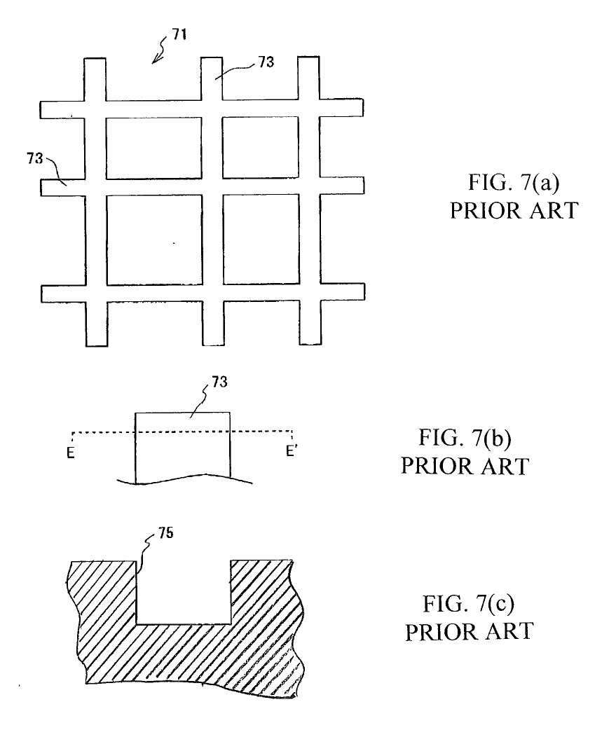

As a comparison example, a conventional alignment mark 71 such as that shown in FIG. 7 was scanned. An image of the alignment mark is shown in FIG. 6(a). A Y-direction scan of the mark along the line D-D′ by the detection-light beam of the alignment-detection device 134 produced the signal profile shown in FIG. 6(b). Comparing FIG. 6(b) with FIG. 2(b), it can be seen that the signal contrast and change in amplitude obtained with the conventional alignment mark 71 is substantially poorer than obtained with the alignment-mark embodiment of FIG. 2(a).

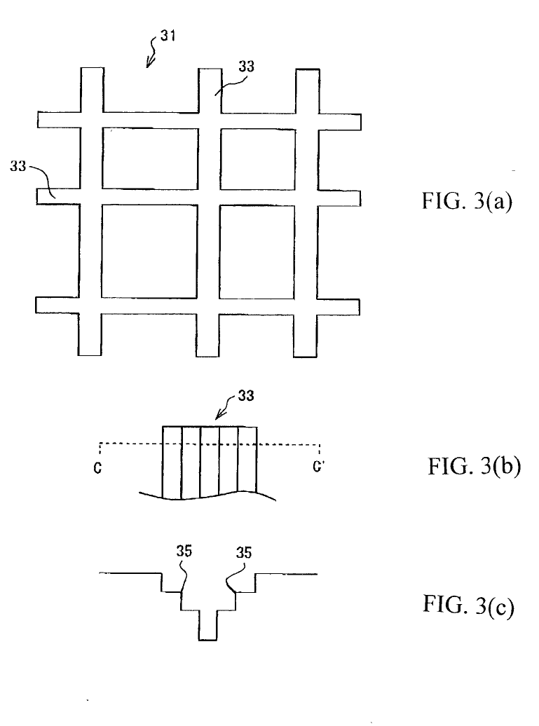

FIGS. 3(a)-3(c) depict a second representative embodiment of an alignment mark 31. FIG. 3(a) is a plan view of the entire alignment mark 31, FIG. 3(b) is an enlargement of a portion of an element 33 of the mark 31, and FIG. 3(c) is an elevational section along the line C-C′ of FIG. 3(b), showing the height-difference profile for each element. As shown in FIG. 3(c), each mark element 33 comprises multiple height changes that correspondingly provide multiple height-difference edges 35. Thus, as the detection-light beam is swept across each element of such an alignment mark, the beam encounters many height-difference edges that scatter the light and produce a stronger profile of signal-amplitude change as detected by the detector.

As described above, an alignment mark according to any of various possible embodiments has more than the conventional two height-difference edges per element. Consequently, each element provides many edges that scatter the detection-light beam swept over the alignment mark. The many scattering events per element substantially increase the signal strength detected by the alignment-detection device, thereby improving the accuracy with which the position of the alignment mark can be detected. By providing such an alignment mark on the reticle, it is possible to detect the position of the reticle with high accuracy, which allows more accurate projection and resolution of the reticle pattern as transferred onto a sensitive substrate.

Whereas the invention has been described in the context of representative embodiments, it will be understood that the invention is not limited to those embodiments. On the contrary, the invention is intended to encompass all modifications, alternatives, and equivalents as may be included within the spirit and scope of the invention, as defined by the appended claims.

What is claimed is:

1. An alignment mark formed on a mark substrate and used for performing an alignment in a charged-particle-beam (CPB) microlithography system, the alignment mark comprising at least one mark element defined as a corresponding height-difference characteristic in the mark substrate, the mark element comprising more than two height-difference edges that would be encountered by a detection-light beam being scanned across the element.

2. The alignment mark of claim 1, wherein the mark substrate is a CPB microlithography reticle.

3. The alignment mark of claim 1, wherein the mark substrate is separate from a CPB microlithography reticle.

4. The alignment mark of claim 1, wherein the mark element comprises multiple individual mark-element components that collectively provide the more than two height-difference edges of the mark element.

5. The alignment mark of claim 4, wherein each component is a line-shaped component of the mark element.

6. The alignment mark of claim 5, wherein the line-shaped components are arranged parallel to each other in the element.

7. The alignment mark of claim 6, wherein the line-shaped components are arranged in the element with a respective prescribed space interval between adjacent line-shaped components.

8. The alignment mark of claim 7, wherein the prescribed space intervals are equal to each other.

9. The alignment mark of claim 7, wherein each prescribed interval is no greater than a resolution limit of an optical system of an alignment-detection device used for detecting the alignment mark.

10. The alignment mark of claim 4, comprising multiple mark elements arranged at right angles to each other, each mark element comprising more than two height-difference edges that would be encountered by a detection-light beam being scanned across the element.

11. The alignment mark of claim 1, wherein the mark element comprises two height-difference edges at respective edges of the mark element and at least one height-difference edge situated between the two height-difference edges at respective edges of the mark element.

12. The alignment mark of claim 11, wherein the at least one height-difference edge situated between the two height-difference edges at respective edges of the mark element is separated from the two height-difference edges at the respective edges of the mark element by a prescribed interval that is no greater than a resolution limit of an optical system of an alignment-detection device used for detecting the alignment mark.

13. The alignment mark of claim 11, comprising multiple mark elements arranged at right angles to each other, each mark element comprising more than two height-difference edges that would be encountered by a detection-light beam being scanned across the element.

14. A reticle for a charged-particle-beam microlithography system, the reticle comprising an alignment mark as recited in claim 1.

15. A reticle for a charged-particle-beam microlithography system, the reticle comprising an alignment mark as recited in claim 4.

16. A reticle for a charged-particle-beam microlithography system, the reticle comprising an alignment mark as recited in claim 11.

17. In a charged-particle-beam microlithography method in which a pattern, defined on a reticle, is transferred to a sensitive substrate using a charged particle beam, a method for detecting an alignment of the reticle, the method comprising:
on the reticle, defining an alignment mark comprising at least one mark element defined as a corresponding height-difference characteristic in the reticle, the mark element comprising more than two height-difference edges that would be encountered by a detection-light beam being scanned across the element.
directing a detection-light beam to the alignment mark and scanning the detection-light beam across the element;
detecting light of the detection-light beam reflected from the alignment mark as the detection-light beam is scanned across the element;
from the detected light, producing a corresponding electrical signal exhibiting amplitude changes corresponding to passage of the detection-light beam over the height-difference edges of the element; and
processing the electrical signal to determine an alignment position of the reticle.

18. The method of claim 17, wherein the mark element comprises multiple individual mark-element components that collectively provide the more than two height-difference edges of the mark element.

19. The method of claim 17, wherein the mark element comprises two height-difference edges at respective edges of the mark element and at least one height-difference edge situated between the two height-difference edges at respective edges of the mark element.
